(19) United States
(12) Patent Application Publication
(10) Pub. No.: US 2026/0262478 A1
(43) Pub. Date: Sep. 3, 2026

(54) WAFER HANDLING SYSTEM AND METHOD

(71) Applicant: SERVICE SUPPORT SPECIALTIES, INC., Montville, NJ (US)

(72) Inventor: Gary HILLMAN, Livingston, NJ (US)

(73) Assignee: SERVICE SUPPORT SPECIALTIES, INC., Montville, NJ (US)

(21) Appl. No.: 18/863,223

(22) PCT Filed: Aug. 28, 2024
(86) PCT No.: PCT/US2024/044262

§ 371 Date: Nov. 5, 2024

Related U.S. Application Data
(60) Provisional application No. 63/582,919, filed on Sep. 15, 2023.

(51) Int. Cl. H10P 72/76; H10P 72/10; H10P 72/30

(52) U.S. Cl. CPC H10P 72/7618; H10P 72/14; H10P 72/3402; H10P 72/3404; H10P 72/3412; H10P 72/7602; H10P 72/7608

(57) ABSTRACT

A wafer handling system and method. The wafer handling system may include a support member and a housing rotatably coupled to the support member. The housing may have a cavity with a first opening in a first side thereof and a second opening in a second side thereof, the second side being opposite the first side. The cavity may have a plurality of slots, each of which may be configured to receive a wafer. The wafers may be inserted into and removed from the cavity through either, or both, of the first and second openings. When the housing is rotated while wafers are located therein, the wafers may be inverted or flipped from a front side up orientation to a front side down orientation.

### CROSS-REFERENCE TO RELATED APPLICATIONS

The present application claims priority to U.S. Provisional Patent Application Ser. No. 63/582,919, filed Sep. 15, 2023, the entirety of which is incorporated herein by reference.

### BACKGROUND OF THE INVENTION

The semiconductor manufacturing industry is one of continuous improvement in processes which has an ongoing need for higher equipment throughput at ever lower cost. Furthermore, due to the considerable costs associated with cleanroom space, there is a need and desire for a smaller footprint. There are situations in semiconductor processing where the back side of the wafer requires processing. To achieve this, the wafer must be inverted, and this action can be time consuming. Thus, a need exists to improve the efficiencies in wafer handling particularly when inverting of the wafer is required.

### SUMMARY OF THE INVENTION

The present invention is directed to a wafer handling system and/or a wafer handling method. The wafer handling system may include a support member and a housing rotatably coupled to the support member. The housing may have a cavity with a first opening in a first side thereof and a second opening in a second side thereof, the second side being opposite the first side. The cavity may have a plurality of slots, each of which may be configured to receive a wafer. The wafers may be inserted into and removed from the cavity through cither, or both, of the first and second openings. When the housing is rotated while wafers are located therein, the wafers may be inverted or flipped from a front side up orientation to a front side down orientation.

In one aspect, the invention may be a wafer handling system comprising: a wafer flipping apparatus comprising: a support member; a housing rotatably coupled to the support member, the housing comprising a cavity, a first side having a first opening into the cavity, and a second side having a second opening into the cavity, the cavity comprising a plurality of slots each configured to receive a wafer such that the cavity is configured to hold a plurality of the wafers in a spaced apart manner; wherein the wafers are configured to be inserted into and removed from the cavity through both of the first and second openings; and wherein during rotation of the housing relative to the support member, the wafers in the cavity are configured to be inverted.

In another aspect, the invention may be a wafer handling method comprising: a) inserting a first set of wafers into a cavity of a housing via a first opening in a first side of the housing with the first set of wafers in a first upright orientation; b) rotating the housing 180° to invert the first set of wafers into a first inverted orientation; c) removing the first set of wafers from the cavity of the housing via a second opening in a second side of the housing while the first set of wafers remain in the first inverted orientation.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 is a front perspective view of a wafer flipping apparatus in accordance with an embodiment of the present invention;

FIG. 2 is a rear perspective view of the wafer flipping apparatus of FIG. 1;

FIG. 3 is a front perspective view of the wafer flipping apparatus with a frame and support legs thereof omitted;

FIG. 4 is a rear perspective view of the wafer flipping apparatus with the frame and the support legs thereof omitted;

FIG. 5 is a cross-sectional view taken along line V-V of FIG. 3;

FIG. 6 is a front perspective exploded view of the wafer flipping apparatus of FIG. 1 with the frame and the support legs thereof omitted;

FIG. 7 is a perspective view of a sidewall of a housing of the wafer flipping apparatus of FIG. 1;

FIG. 8A is first side perspective view of a gripper member of the wafer flipping apparatus of FIG. 1;

FIG. 8B is a second side perspective view of the gripper member of FIG. 8A;

FIG. 9A is a perspective view of the housing of the wafer flipping apparatus of FIG. 1 with the gripper members in a non-clamped position;

FIG. 9B is a perspective view of the housing of the wafer flipping apparatus of FIG. 1 with the gripper members in a clamped position;

FIG. 10A is a close-up view of area XA of FIG. 9A;

FIG. 10B is a close-up view of area XB of FIG. 9B;

FIGS. 11A-11C illustrate the housing of the wafer flipping apparatus of FIG. 1 rotating relative to a support member thereof;

FIG. 12 is a schematic illustration of a wafer handling system that includes the wafer flipping apparatus of FIG. 1 and first and second robot apparatus that are configured to insert wafers into and remove wafers from the housing of the wafer flipping apparatus;

FIGS. 13A-13I illustrate the sequential operation of the wafer handling system; and

FIG. 14 is a flow chart describing the operation of the wafer handling system.

### DETAILED DESCRIPTION OF THE INVENTION

The following description of the preferred embodiment(s) is merely exemplary in nature and is in no way intended to limit the invention, its application, or uses.

The description of illustrative embodiments according to principles of the present invention is intended to be read in connection with the accompanying drawings, which are to be considered part of the entire written description. In the description of embodiments of the invention disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” and similar refer to a relationship wherein structures are secured or attached to one another either directly or indirectly through intervening structures, as well as both movable or rigid attachments or relationships, unless expressly described otherwise. Moreover, the features and benefits of the invention are illustrated by reference to the exemplified embodiments. Accordingly, the invention expressly should not be limited to such exemplary embodiments illustrating some possible non-limiting combination of features that may exist alone or in other combinations of features; the scope of the invention being defined by the claims appended hereto.

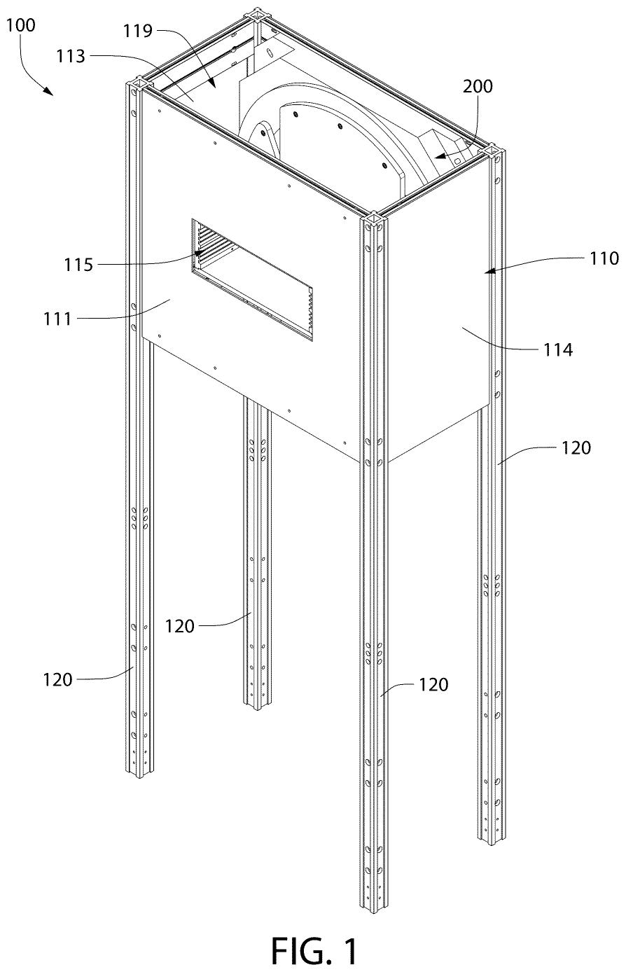

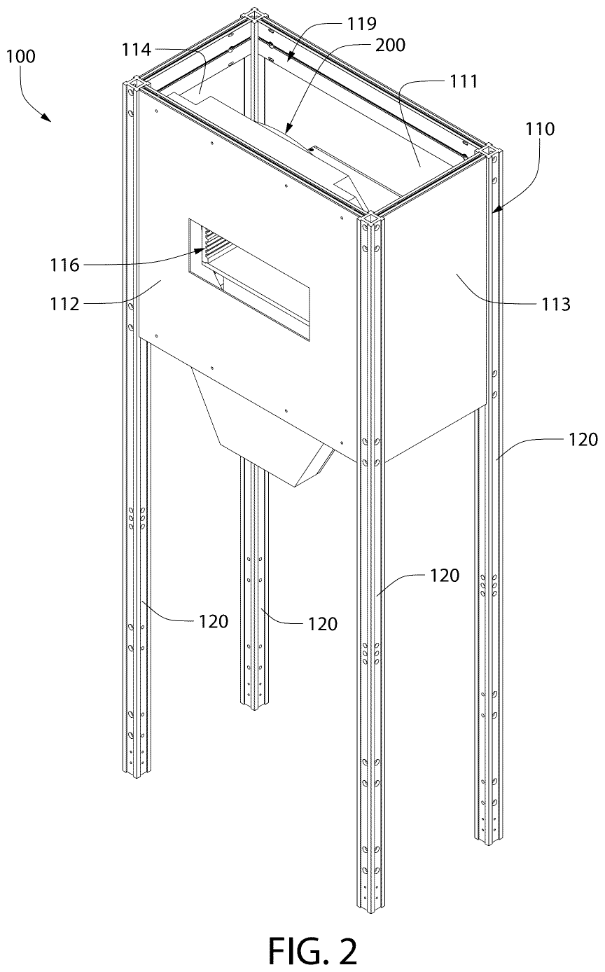

Referring to FIGS. 1 and 2, a wafer flipping apparatus 100 will be described. The wafer flipping apparatus 100 may comprise a frame 110 that defines an enclosure 119, a plurality of supporting legs 120 coupled to the frame 110, and a wafer flipping device 200 coupled to the frame 110 and located within the enclosure 119 defined by the frame 110. The frame 110 may comprise a front frame wall 111, a rear frame wall 112, a first side frame wall 113, and a second side frame wall 114 that collectively define the enclosure 119 as a space bounded by the various frame walls 111-114. The frame walls 111-114 may be coupled together. The wafer flipping device 200 may be mounted or otherwise coupled to the rear frame wall 112. The supporting legs 120 may extend from the frame walls 111-114 downwardly to support the frame 110 on a ground surface, such as on a floor or the like. Thus, the frame 110 and the wafer flipping device 200 supported thereby may be maintained in an elevated position relative to a support surface such as a floor due to the legs 120. The front frame wall 111 may comprise a front frame opening 115 through which the wafer flipping device 200 may be accessed. The rear frame wall 112 may comprise a rear frame opening 116 through which the wafer flipping device 200 may be accessed. The front and rear frame openings 115, 116 may be aligned with openings of the wafer flipping device 200 as described below.

In some embodiments, the frame 110 and/or the supporting legs 120 may be omitted. For example, the wafer flipping device 200 may be supported on a table or counter or the like, such that the supporting legs 120 may not be needed. Furthermore, the wafer flipping device 200 may be mounted to another structure, such as a wall, a partition, a barrier, or the like, such that the frame 110 may not be needed.

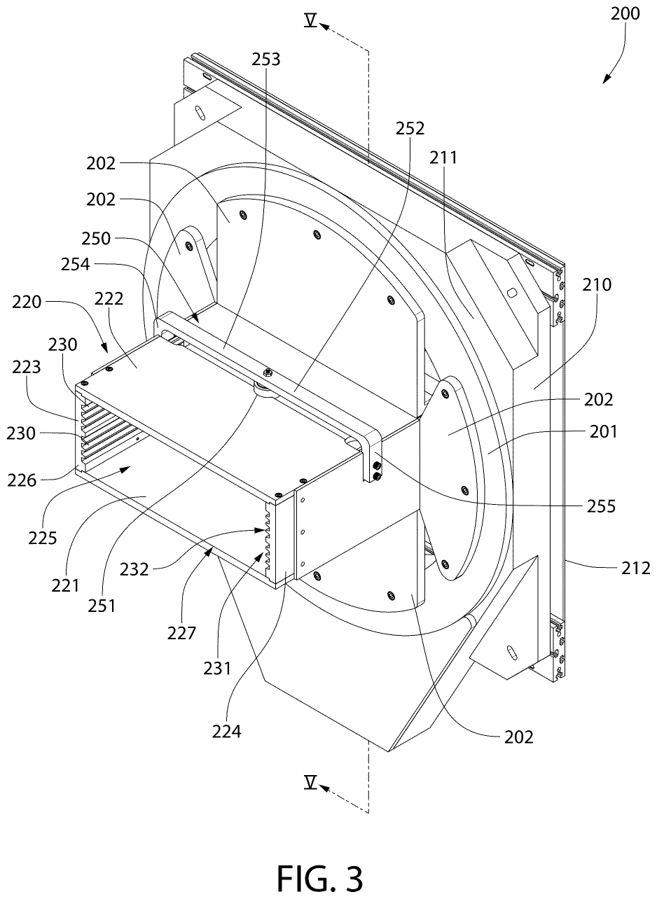

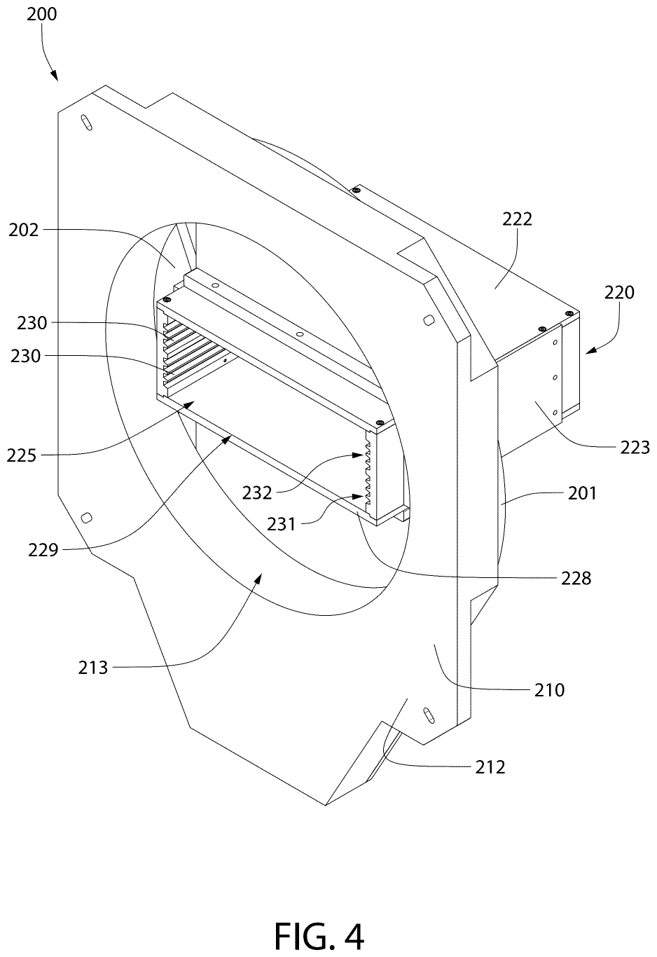

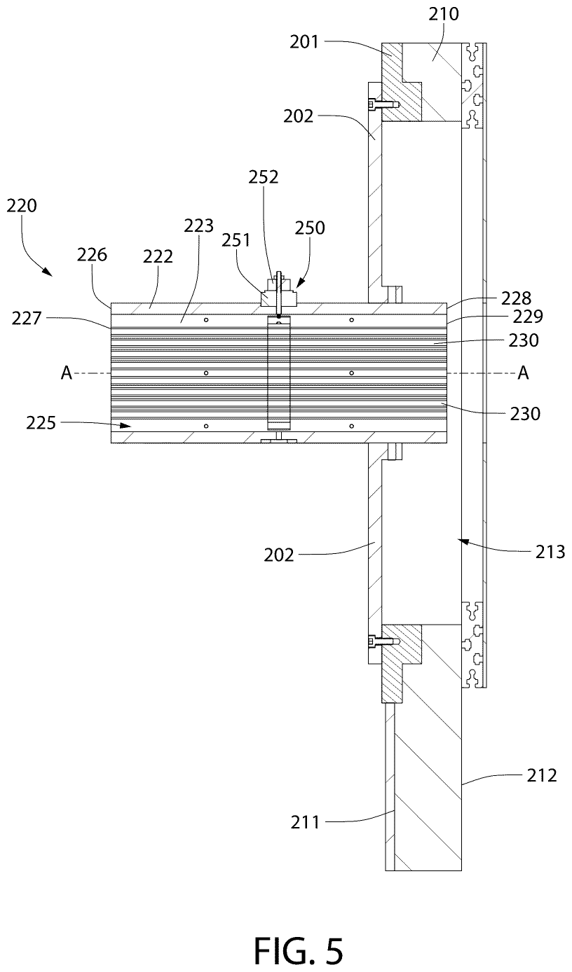

Referring to FIGS. 3-5, the wafer flipping device 200 will be described. The wafer flipping device 200 may comprise a support member 210 and a housing 220 that is rotatably coupled to the support member. In embodiments of the invention, the housing 220 may be rotatably coupled directly to the support member 210. However, in the exemplified embodiment, the wafer flipping device 200 comprises a ring member 201 that is rotatably coupled to the support member 210, and the housing 220 is affixed or coupled to the ring member 201. Thus, in the exemplified embodiment the housing 220 is non-rotatable relative to the ring member 201, but rather the ring member 201 and the housing 220 rotate together relative to the support member 210. Furthermore, in the exemplified embodiment the housing 220 is indirectly coupled to the support member 210 via the ring member 201, although in other embodiments the housing 220 may be directly rotatably coupled to the support member 210 as mentioned. The support member 210 and the ring member 201 may form a rotary actuator or a rotary table or the like, such that the ring member 201 is configured to rotate relative to the support member 210.

The support member 210 may comprise a first surface 211 and a second surface 212 opposite the first surface 211. The first and second surfaces 211, 212 of the support member 210 may be vertically oriented when the wafer flipping device 200 is installed at a desired location, such as in a semiconductor processing or fabrication plant or the like. The support member 210 may comprise a through-hole 213 extending from the front surface 211 to the rear surface 212. The housing 220 may be coupled to the support member 210 (directly or indirectly as described above) so that at least a portion of the housing 220 extends into the through-hole 213. In the exemplified embodiment, a first portion of the housing 220 protrudes from the first surface 211 of the support member 210 and a second portion of the housing 220 is located within the through-hole 213 of the support member 210 with no portion of the housing 220 protruding from the second surface 212 of the support member 210. In alternative embodiments, the housing 220 may protrude from both of the first and second surfaces 211, 212 of the support member 210. The housing 220 may protrude perpendicularly from the front surface 211 of the support member 210. Wafers held in the housing 220 may be oriented horizontally with their front and back surfaces lying in respective horizontal planes.

The ring member 201 and/or the housing 220 may be configured to rotate 360° relative to the support member 210. The ring member 201 and/or the housing 220 may be configured to rotate relative to the support member 210 in one rotational direction (i.e., counterclockwise or clockwise) or in both opposing rotational directions. In other embodiments, the ring member 210 and/or the housing 220 may be configured to rotate 180° (or a full 360°) relative to the support member 210 in two opposite rotational directions. That is, the ring member 210 and/or the housing 220 may be configured to rotate 180° (or more) in one direction (e.g., clockwise) and to then rotate 180° (or more) in the opposite direction (counterclockwise).

In the exemplified embodiment, the housing 220 is coupled to the ring member 201 with one or more attachment plates 202. Each of the attachment plates 202 may be coupled to the housing 220 and to the ring member 210 to secure the attachment of the housing 220 to the ring member 201. The housing 220 and the ring member 201 may each be attached to the various attachment plates 202 with fasteners such as screws. In other embodiments, the attachment between the attachment plates 202 and the housing 220 and/or ring member 201 may be achieved with bolts, nails, friction fit, interference fit, or other known attachment techniques. Regardless of the specific manner in which the various parts are coupled together, the housing 220 is rotatable relative to the support member 210 so that any wafers supported in the housing 220 can be inverted or flipped, as described below.

The housing 220 may comprise a bottom wall 221, a top wall 222, a first side wall 223, and a second side wall 224 that are coupled together as shown. The bottom, top, first side, and second side walls 221-224 may be coupled together with fasteners such as screws, although alternative attachment techniques may be used in other embodiments. The housing 220 may define a cavity 225 that is configured to receive and hold a plurality of wafers, such as semiconductor wafers. Thus, the cavity 225 of the housing 220 may be sized and shaped so as to be capable of receiving a plurality of wafers of a desired size. The size of the housing 220 and the cavity 225 may be modified depending on the size/diameter of the wafers intended to be received therein.

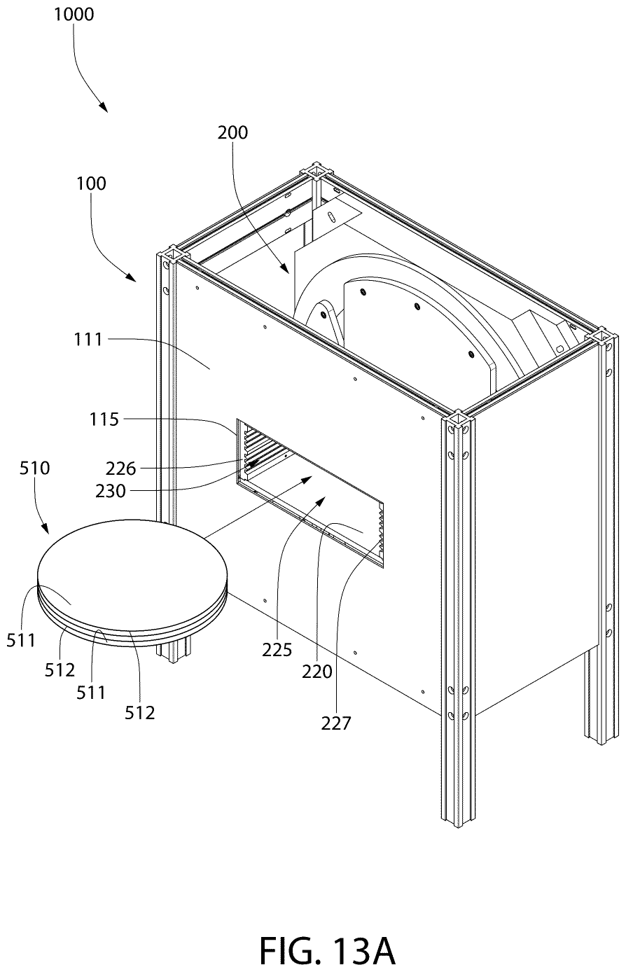

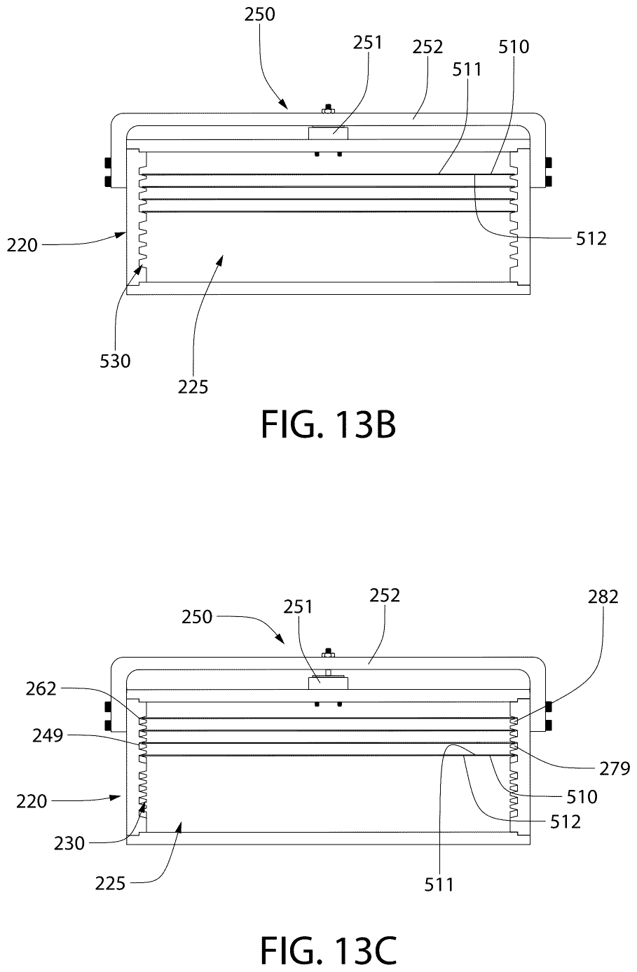

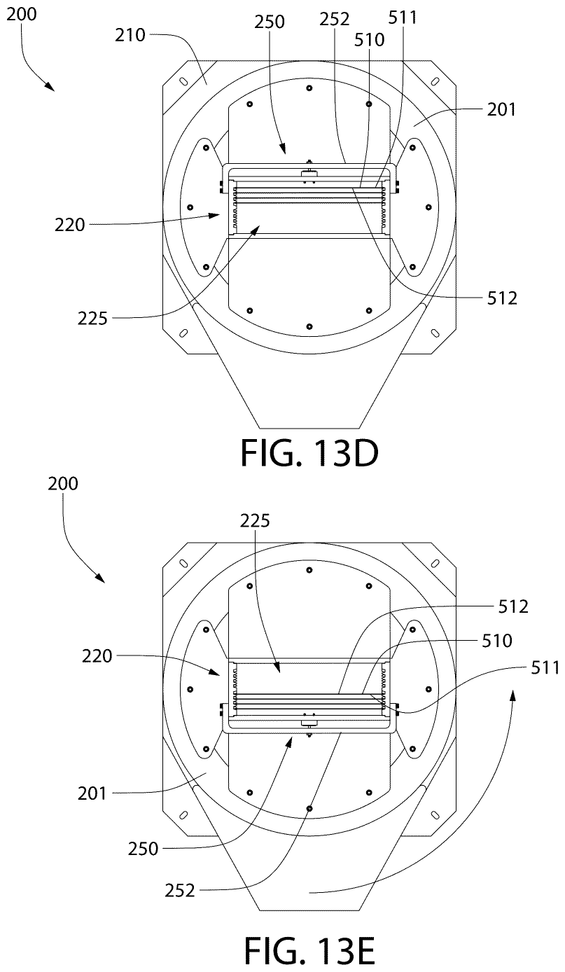

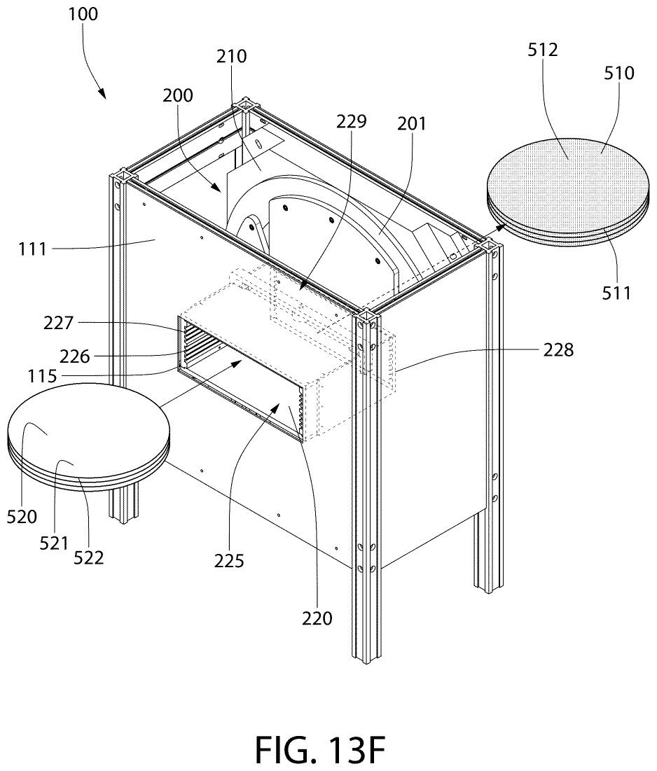

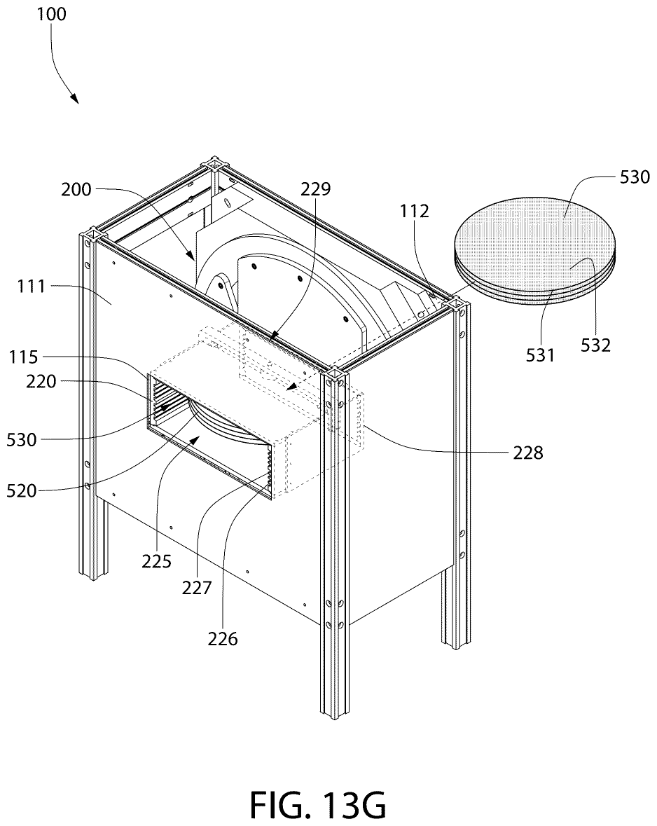

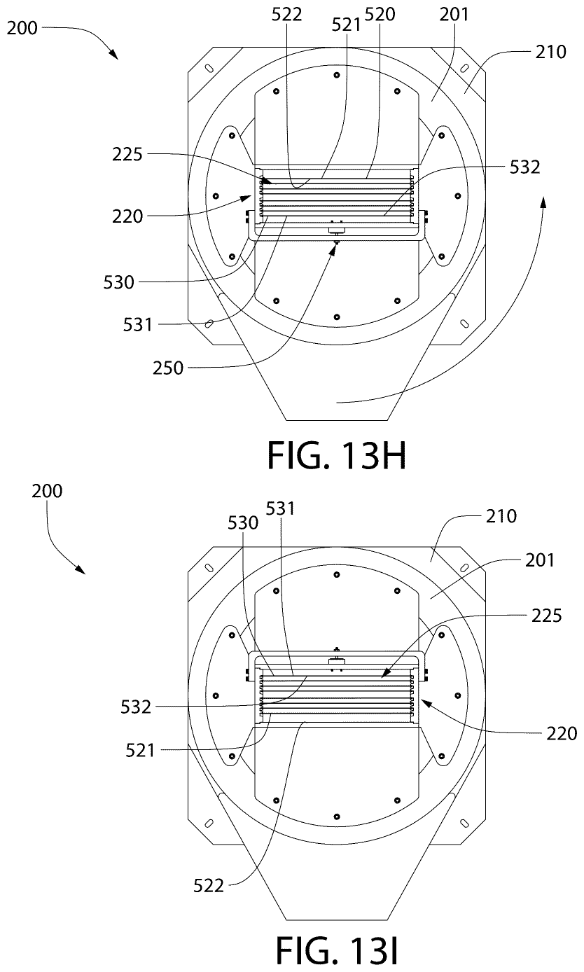

The housing 220 may comprise a first side or a first end 226 having a first opening 227 into the cavity 225 and a second side or a second end 228 having a second opening 229 into the cavity 225. The second side 228 may be opposite to the first side 226. The cavity 225 may have a cavity axis A-A that extends from the first side 226 to the second side 228. The cavity 225 is open at both of its first and second sides/ends 226, 228 due to the first and second openings 227, 229. In an embodiment, the second side 228 may be located within the through-hole 213 of the support member 210. In other embodiments, the second side 228 may be located beyond the second surface 212 of the support member 210. The first and second openings 227, 229 may have the same dimensions. Each of the first and second openings 227, 229 may be sized and configured so that the wafers desired to be held in the cavity 225 are capable of passing through each of the first and second openings 227, 229. Thus, the wafers may be inserted into the cavity 225 through the first opening 227 and through the second opening 229. Similarly, the wafers may be removed from the cavity 225 through the first opening 227 and through the second opening 229. Depending on where the wafers are being transported to and from, the wafers may be inserted into and removed from the cavity 225 via each of the first and second openings 227, 229 during processing, the details of which will be described with reference to FIGS. 13A-13I below. For example, the wafers or a group of the wafers may be inserted into the cavity 225 through the first opening 227, then the housing 220 may be rotated 180° to invert the wafers, and then the group of the wafers may be removed from the cavity 225 through the second opening 229. The opposite may also occur, with the wafers being inserted into the cavity 225 through the second opening 229, then the housing 220 may be rotated 180° to invert (or un-invert) the wafers, and then the group of wafers may be removed from the cavity 225.

The cavity 225 may comprise a plurality of slots 230. The slots 230 may be defined by slits or channels formed into the inner surfaces of the first and second side walls 223, 224 of the housing 225, which will be described in more detail below with reference to FIG. 7. The slots 230 may be configured to hold wafers in a spaced apart manner within the cavity 225. Specifically, the slots 230 may be spaced apart in a vertical direction between the bottom wall 2221 and the top wall 222 so that each slot 230 is configured to receive and hold a wafer. Due to the spacing between the slots 230, the wafers held therein are maintained in a spaced apart manner from one another even when a wafer is located in each of the slots 230. In the exemplified embodiment, there are eight of the slots 230. This may include two sets of slots, including a group of lower slots 231 and a group of upper slots 232. There may be four of the lower slots 231 and four of the upper slots 232. However, there may be greater than or fewer than eight of the slots 230 in other embodiments. In some embodiments, there are preferably an even number of the slots 230. In some embodiments, there may be at least four of the slots 230. In some embodiments, there may be at least six of the slots 230. In some embodiments, there may be at least eight of the slots 230. In some embodiments, there may be at least ten of the slots 230.

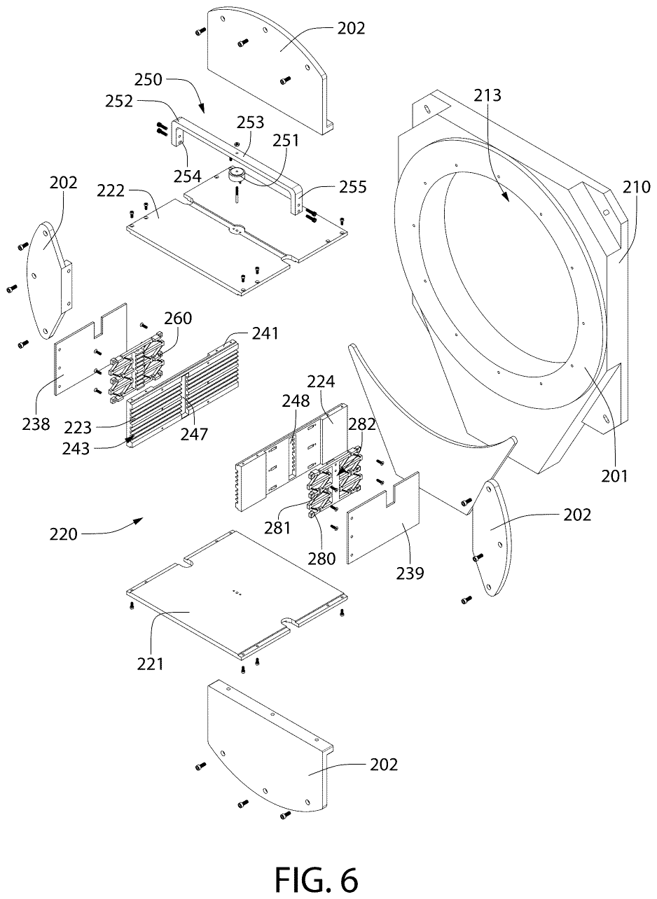

Referring to FIG. 6, the various components of the wafer flipping device 200 will be further described. FIG. 6 illustrates the various components in an exploded state. The support member 210 and the ring member 201 remain coupled in this view. As noted above, the ring member 201 is configured to rotate relative to the support member 210. The bottom wall 221, the top wall 222, the first side wall 223, and the second side wall 224 of the housing 220 are illustrated, as well as the various attachments plates 202 that are used to attach the housing 220 to the ring member 201.

In addition to the components previously mentioned, FIG. 6 also illustrates a first gripper member 260 and a second gripper member 280. The first gripper member 260 is associated with and works in conjunction with the first side wall 223. That is, the first gripper member 260 may be coupled to or positioned adjacent to the first side wall 223. The second gripper member 280 is associated with and works in conjunction with the second side wall 224. That is, the second gripper member 280 may be coupled to or positioned adjacent to the second side wall 224. In an embodiment, a first side cover 238 is coupled to the first side wall 223, thereby sandwiching the first gripper member 260 between the first side cover 238 and the first side wall 223. Similarly, in an embodiment a second side cover 239 is coupled to the second side wall 224, thereby sandwiching the second gripper member 280 between the second side cover 239 and the second side wall 224. Of course, other means of attachment and for properly securing the first and second gripper members 260, 280 may be used. Furthermore, while the first and second gripper members 260, 280 are used in the disclosed embodiment to clamp and secure the wafers during rotation of the housing 220, in other embodiments other clamping structures may be used.

FIGS. 3, 5, and 6 further illustrate an actuation assembly 250 that is operably coupled to the first and second gripper members 260, 280 and configured to alter the first and second gripper members 260, 280 between a clamped position and a non-clamped position. The actuation assembly 250 may comprise an actuator device 251 and an actuation member 252 that is operably coupled to the actuator device 251 and to each of the first and second gripper members 260, 280. In the exemplified embodiment, the actuator device 251 is a linear solenoid, although other devices may be used to achieve the movement of the first and second gripper members 26, 280. In the exemplified embodiment, the actuator member 252 is a bar that is coupled to the actuator device 251 and to each of the first and second gripper members 260, 280.

The actuator member 252 may comprise an elongated central portion 253 having a first end and a second end, a first flange portion 254 extending downwardly from the first end of the central portion 253 and a second flange portion 255 extending downwardly from the second end of the central portion 253. The first flange portion 254 may be coupled to the first gripper member 260 and the second flange portion 255 may be coupled to the second gripper member 280. In the exemplified embodiment, fasteners such as screws are used to facilitate the attachment of the first and second flange portions 254, 255 to the first and second gripper members 260, 280, respectively. However, other attachment means may be used in other embodiments, including friction fit, slide fit, mechanical engagement, bolts, rivets, or the like. Due to the coupling between the actuator member 252 and the first and second gripper members 260, 280, linear movement of the actuator member 252 may generate a linear movement of a portion of the first and second gripper members 260, 280. The linear movement of the portions of the first and second gripper members 260, 280 may be used to secure/clamp the wafers within the cavity 225 of the housing 220 during rotation of the housing 220 as described herein.

When the actuator device 251 is actuated, the actuator device 251 causes the actuator member 252 to move vertically either upwardly away from the top wall 222 of the housing or downwardly towards the top wall 222 of the housing 220. Furthermore, due to the attachment of the actuator member 252 to the first and second gripper members 260, 280, the movement of the actuator member 252 upwardly or downwardly causes a similar movement to a portion of the first and second gripper members 260, 280, which causes the first and second gripper members 260, 280 to alter between clamped and un-clamped states, as described further below.

Referring to FIG. 7, the first side wall 223 of the housing 220 will be described, it being understood that the second side wall 224 is identical to the first side wall 223. Thus, the description of the first side wall 223 is applicable to the second side wall 224 in all respects. The first side wall 223 comprises an inner surface 240 and an outer surface 241 opposite the inner surface 240. The inner surface 240 of the first side wall 223 faces and therefore bounds a part of the cavity 225 of the housing 220. As noted, the first side wall 223 comprises a plurality of slits (or channels) 243 that are formed into the inner surface 240 of the first side wall 223. Each of the slits 243 in the first side wall 223 is aligned in a vertical direction with a slit of the second side wall 224 to form a pair of slits, and each of the pairs of slits forms one of the slots 230 of the cavity 225 as described above.

Each of the slits 243 is defined by a slit edge wall 244, a slit top wall 245, and a slit bottom wall 246. In an embodiment, the slit top walls 245 are angled upwardly relative to the slit edge wall 244 and the slit bottom walls 246 are angled downwardly relative to the slit edge wall 244. This ensures that the slit top and bottom walls 245, 246 do not directly contact the front and rear surfaces of the wafer held in the slit 243. Rather, the slit top and/or bottom walls 245, 246 may only contact an edge of the wafer that is defined between a peripheral surface and one of the front and rear surfaces of the wafer. In an embodiment, each of the slits 243 has a minimum height measured between the slit top wall 245 and the slit bottom wall 246 at a position where the slit top and bottom walls 245, 246 contact the slit edge wall 245. In an embodiment, the height of the slits 243 may be greater than a thickness of the wafers intended to be supported therein. Each of the first and second side walls 223, 224 may have eight of the slits 243, or a number of slits that matches the slots of the cavity 225 as described above.

The first side wall 223 may comprise a first edge 235 and a second edge 236 opposite the first edge 235. The first and second edges 235, 236 may each extend between the front and rear surfaces 240, 241. The first edge 235 may form a portion of the first side 226 of the housing 220 where the first opening 227 is located. The second edge 236 may form a portion of the second side 228 of the housing 220 where the second opening 229 is located. The first side wall 223 may be elongated between the first and second edges 235, 236. Each of the slits 243 may extend and be elongated from the first edge 235 to the second edge 236. Thus, each of the slits 243 may be open at the first edge 235 (and the first side 226 of the housing 220) and at the second edge 236 (and at the second side 228 of the housing 220) to facilitate insertion of the wafers into the various slits 243. However, in an embodiment the slits 242 may be discontinuous along the length of the first side wall 223 (for example, due to an opening in the fist side wall 223 as described below).

The first side wall 223 may comprise a first wall opening 247 (and similarly, the second side wall 224 may comprise a second wall opening, as shown in FIG. 6). The first wall opening 247 may be elongated in a vertical direction between the top and bottom edges of the first side wall 223. The first wall opening 247 may extend through the thickness of the first side wall 223 from the inner surface 240 to the outer surface 241. The first wall opening 247 may be located centrally between the first side edge 235 of the first side wall 223 and the second side edge 236 of the first wall 223. Each of the slits 243 may extend from the first edge 235 to a first side of the first wall opening 247 and also from the second edge 236 to a second side of the first wall opening 247. Thus, the first wall opening 247 may result in the slits 243 being discontinuous such that there is a gap in the slits 243 at the location of the first wall opening 247. In the exemplified embodiment, the first wall opening 247 is a singular continuous opening. In other embodiments, the first wall opening 247 may comprise multiple distinct openings.

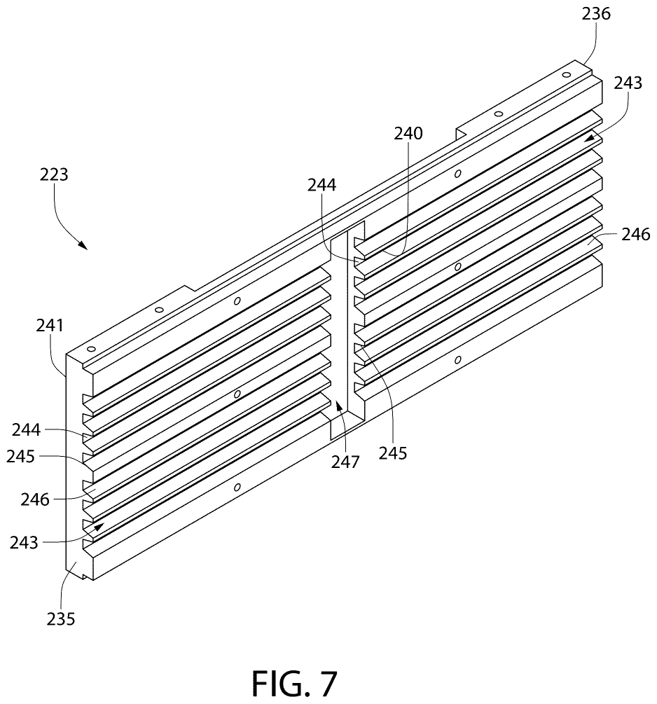

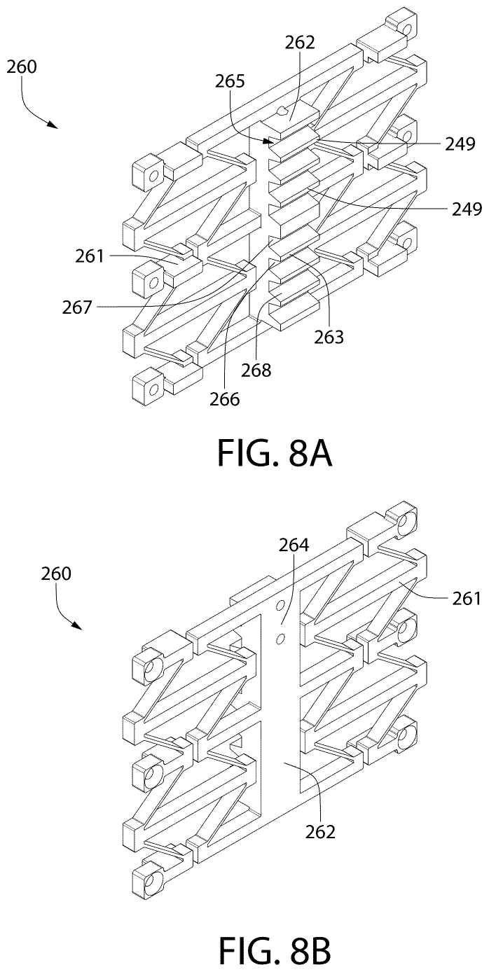

Referring to FIGS. 8A and 8B, the first gripper member 260 will be described. In an embodiment, the second gripper member 280 may be identical to the first gripper member 260. Thus, the description of the first gripper member 260 may be applicable to the second gripper member 260.

The first gripper member 260 may comprise a first gripper body 261 and a first gripper element 262. The first gripper element 262 may be located centrally along the first gripper body 261 so that a first portion of the first gripper body 261 is located on a first side of the first gripper element 262 and a second portion of the first gripper body 261 is located on a second side of the first gripper element 262. Of course, other configurations for the first gripper member 260 may be used in other embodiments. The first gripper member 260 may be configured so that the first gripper element 262 is capable of moving vertically upwardly and downwardly relative to the first gripper body 261. This may be due to the first flange 254 of the actuator member 252 being coupled to the first gripper element 262 of the first gripper member 260. The movement of the first gripper element 262 may facilitate the clamping of the wafers while the housing 220 is rotated, as described further below.

The first gripper element 262 comprises an inner surface 263 and an outer surface 264. The first gripper element 262 comprises a plurality of first gripper slits (or channels) 265 in the inner surface 263. Each of the slits 243 is defined between a pair of rib-like protrusions 249 of the first gripper element 262. Similar to the slits 243 of the first side wall 223, the first gripper slits 265 are defined by a gripper slit edge wall 266, a gripper slit top wall 267, and a gripper slit bottom wall 268. The gripper slit top and bottom walls 267, 268 are formed by the top and bottom surfaces of the rib-like protrusions 249. The first gripper slits 265 may have the same size and configuration as the slits 243 of the first side wall 223. Thus, the gripper slit top wall 267 may extend from and be angled upwardly relative to the gripper slit edge wall 266 and the gripper slit bottom wall 268 may extend from and may be angled downwardly relative to the gripper slit edge wall 266. Each of the gripper slits 265 may be configured to receive a portion of a wafer when the wafer is in one of the slots 230 of the housing 220 as described herein.

Referring briefly to FIG. 6, the first gripper member 260 may be positioned adjacent to the outer surface 241 of the first side wall 223 such that the first gripper element 262 protrudes into the first wall opening 247. As such, the first gripper slits 265 may be aligned with the slits 243 of the first side wall 223. Similarly, the second gripper member 280 may comprise a second gripper body 281 and a second gripper element 282. The second gripper member 280 may be positioned adjacent to an outer surface of the second side wall 224 such that the second gripper element 282 protrudes into the second wall opening 248. As such, the second gripper slits may be aligned with the slits of the second side wall 224.

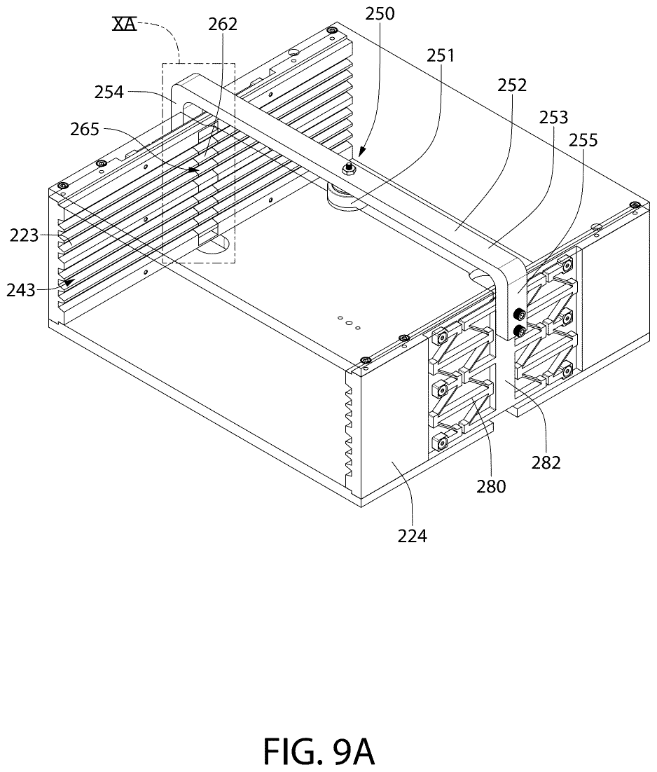

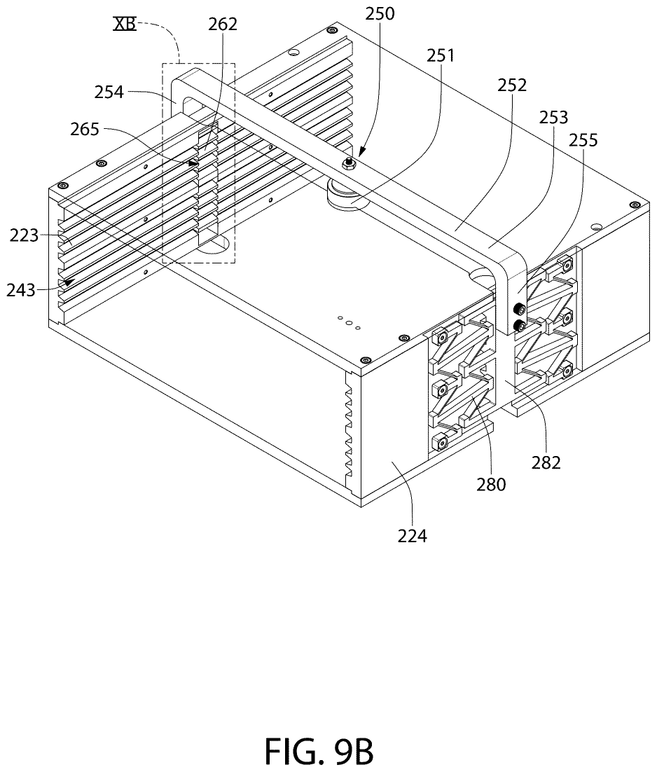

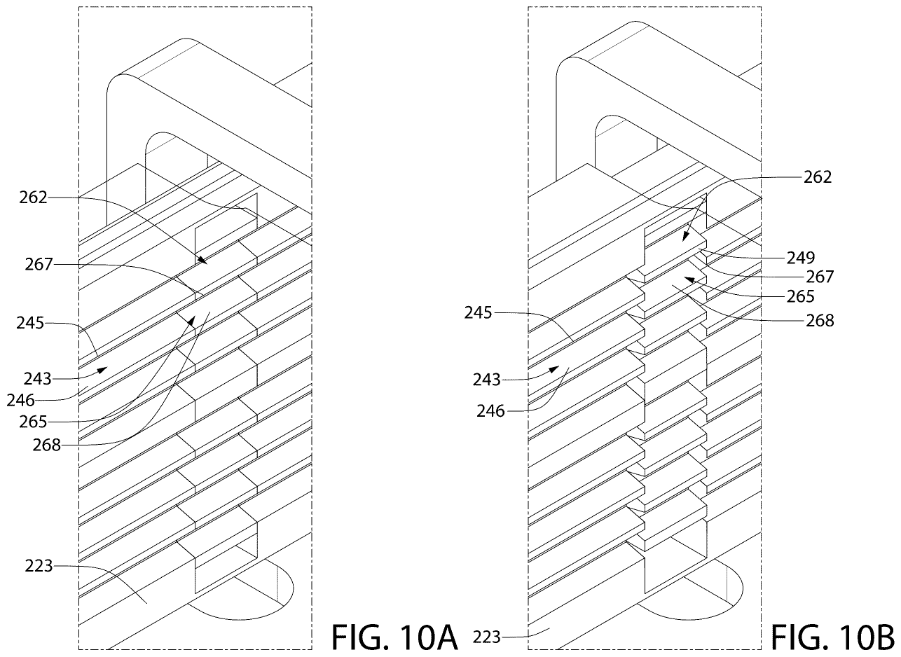

Referring to FIGS. 9A-10B, the function and operation of the first gripper member 260 will be described. It should be understood that in accordance with the exemplified embodiment, the second gripper member 280 operates in the same manner, and simultaneously with, the first gripper member 260. Thus, the function and operation of the first gripper member 260 described herein is applicable to the second gripper member 280. As seen in FIGS. 9A and 9B, the actuation member 252 of the actuation assembly 250 is coupled to each of the first and second gripper members 260, 280 with fasteners such as screws. More specifically, the first flange 254 of the actuation member 252 is coupled to the first gripper element 262 of the first gripper member 260 and the second flange 255 of the actuation member 252 is coupled to the second gripper element 282 of the second gripper member 280. Thus, movement of the actuation member 252 vertically upwardly or downwardly will cause similar movement to the first and second gripper elements 262, 282 of the first and second gripper members 260, 280, respectively.

In FIGS. 9A and 10A, the actuation assembly 250 is in a non-actuated state. With the actuation assembly 250 in the non-actuated state, the first gripper slits 265 of the first gripper element 262 are aligned with the slits 243 of the first side wall 223. That is, the slits 243 and the first gripper slits 265 form a continuous slit, with the slit top walls 245 being aligned with the gripper slit top walls 267 and the slit bottom walls 246 being aligned with the gripper slit bottom walls 268.

Referring to FIGS. 9B and 10B, the actuation assembly 250 is in an actuated state. Specifically, the actuator device 251 of the actuation assembly 250 has been actuated/activated to move the actuation member 252 in a vertically upward direction relative to its position in FIGS. 9A and 10A. The elevated nature of the actuation member 252 is readily apparent from a comparison of FIG. 9B with FIG. 9A. Due to the attachment of the actuation member 252 to the first and second gripper elements 262, 282 of the first and second gripper members 260, 280, the vertically upward movement of the actuation member 252 causes the first and second gripper elements 262, 282 to also move vertically upward. Specifically, the first gripper element 262 moves vertically upward relative to the first gripper body 261 and relative to the first side wall 223, which both remain static. Similarly, the second gripper element 282 moves vertically upward relative to the second gripper body 281 and relative to the second side wall 224, which both remain static.

Turning to FIG. 10B, it can be seen that the first gripper slits 265 are no longer fully aligned with the slits 243 of the first side wall 223 (and similar with the second gripper slits and the slits of the second side wall 224). That is, because the first gripper element 252 has moved vertically upwardly while the first side wall 223 has remained static, the rib-like protrusions 249 of the first gripper element 252 which define the first gripper slits 265 between them are now aligned with the slits (or channels) 243 of the first side wall 223.

If a wafer were located in the cavity 225 of the housing 220 during this actuation of the actuation assembly 250, the movement of the rib-like protrusions 249 upwardly will clamp and secure the wafers so that they do not move during rotation of the housing 220. Specifically, the wafers will be clamped between the gripper slit bottom walls 268 of the gripper element 262 and the slit top walls 245 of the first side wall 223 in a sufficient manner to prevent the wafers from sliding out through the first and second openings 227, 229 of the housing 220 during rotation of the housing 220. The wafers may be clamped between the gripper element 262 and the first side wall 223 to prevent any movement of the wafers at all in some embodiments.

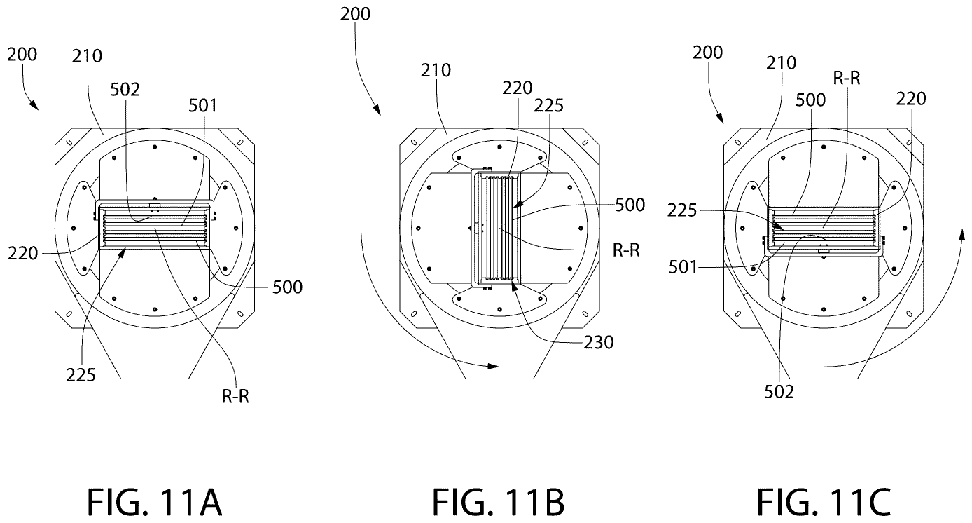

FIGS. 11A-11C schematically illustrate the rotation of the housing 220 relative to the support member 210 of the wafer flipping device 200. In FIGS. 11A-11C, the housing 220 rotates in a counterclockwise direction. In other embodiments, the housing 220 may rotate in a clockwise direction. In still other embodiments, the housing 220 may be capable of rotating in either of the clockwise and counterclockwise directions. FIGS. 11A-11C illustrate the housing 220 with a plurality of wafers 500 located therein. Each of the wafers 500, is located within one of the slots 230 of the cavity 225. Furthermore, the first and second gripper members (not visible) are in their clamped state or position so that the wafers 500 are clamped and secured in place so that they do not move significantly (or at all) during the rotation of the housing 220. In FIG. 11C, the housing 220 has rotated 180° relative to the support member 210. As such, the housing 220 and the wafers 500 held therein are inverted relative to their orientation with the housing in its upright position as shown in FIG. 11A.

Specifically, each of the wafers 500 may have a front side or surface 501 and a back side 502 or surface. In some embodiments, the front side 501 may be the device side of the wafer 500 and the back side 502 may be the non-device side of the wafer 500. In other embodiments, the front side 501 may be the non-device side and the back side 502 may be the device side. Thus, in FIG. 11A, the wafers 500 may be positioned in the cavity 225 of the housing 220 with the front side 501 up and the back side 502 down. Specifically, the front side 501 may be facing upwardly and the back side 502 may be facing downwardly. Once the housing 220 is rotated 180° to the position shown in FIG. 11C, the wafers 500 are all inverted such that the front side 501 is now facing downwardly and the back side 502 is now facing upwardly. The wafers 500 can then be removed from the cavity 225 in this inverted orientation with the back side 502 facing upwardly for processing, and specifically for back side processing operations.

In an alternative embodiment, the wafers 500 may first be placed into the cavity 225 in the inverted orientation with the back side 502 facing upwardly. Then, when the housing 220 is rotated 180° the wafers 500 are inverted so that the back side 502 is facing downwardly and the front side 501 is facing upwardly. Thus, the inverting of the wafers 500 can be from front side up to front side down of from back side up to back side down, depending on need in a particularly processing system. As used herein, the term invert or inverted or inverting means flipping the wafer 500 to alter which of the front and back sides 501, 502 of the wafer 500 is facing upwardly.

During the rotation, the housing 220 rotates about a rotational axis R-R that is parallel to the cavity axis A-A. In an embodiment, the rotational axis R-R of the housing 220 may be the same as the cavity axis A-A. The rotational axis R-R of the housing 220 is parallel to the front and back sides 501, 502 of the wafers 500 in order to invert the wafers 500 as a result of the 180° rotation of the housing 220. The rotational axis R-R of the housing 220 intersects both of the first and second openings 227, 229 of the housing 220.

The wafers described herein may be those that are used in the semiconductor industry and may be described herein as semiconductor wafers or simply wafers, raw silicon substrates, flat articles, panels, or the like. Typically, the substrate is a flat article used in the fabrication of an integrated circuit, although the invention is not to be so limited in all embodiments. Such substrates or wafers may be formed from a thin slice of a semiconductor material, such as a crystalline silicon.

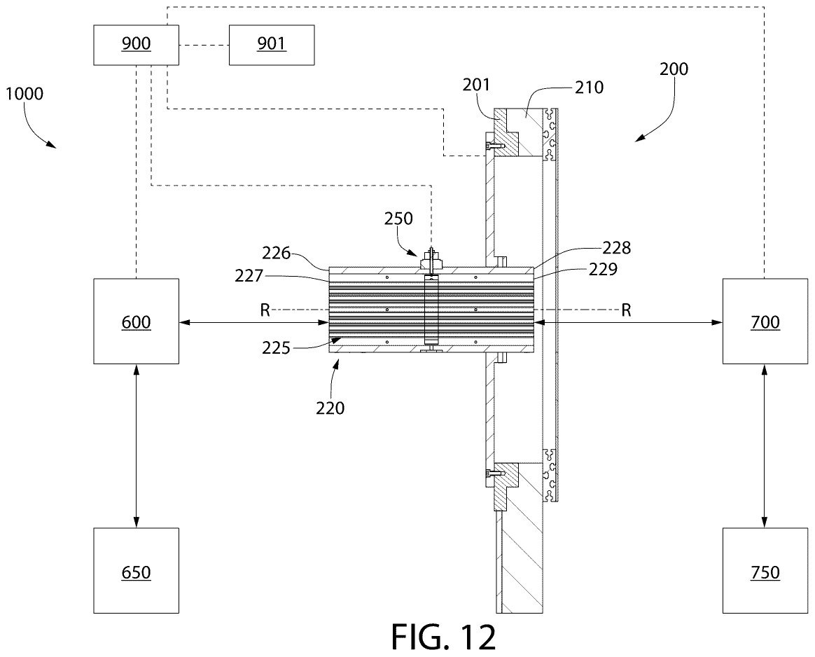

Referring to FIG. 12, a wafer handling system 1000 that comprises the wafer flipping device 200 will be described. The wafer handling system 1000 comprises the wafer flipping device 200 (or the wafer flipping apparatus 100), a first robot apparatus 600, a second robot apparatus 700, a storage pod 650, and a tool 750. The wafer handling system 1000 may further comprise one or more controllers or processors 900 operably coupled to the first and second robot apparatuses 600, 700 and to the wafer flipping device 200. The controller 900 may also be operably coupled to the actuation assembly 250 of the wafer flipping device 200. The wafer handling system 1000 may further comprise one or more power sources 901 operably coupled to the first and second robot apparatuses 600, 700 and to the wafer flipping device 200 (either directly or via a connection of the power source 901 to the controller 900). The controller 900 may store instructions so that operation of the wafer handling system 1000 is automated. This may include the movement of the first and second robot apparatuses 600, 700, the actuation of the actuation assembly 250, and the rotation of the housing 220.

The storage pod 650 may be a front opening universal pod or any other storage structure configured to store the wafers. That is, the storage pod 650 may be a carrier designed to securely hold wafers prior to handling and processing. The first robot apparatus 600 may be configured to retrieve one of more wafers from the storage pod 650 and insert the one or more wafers into the cavity 225 of the housing 220 via the first opening 227 in the first side 226 of the housing 220. The first robot apparatus 600 may be configured to retrieve one wafer from the storage pod 650, or the first robot apparatus 600 may be configured to retrieve multiple of the wafers from the storage pod 650 at a time.

The first robot apparatus 600 may be known as the equipment front end module in some embodiments. The first robot apparatus 600 may be configured to insert the wafers into and remove the wafers from the cavity 225 of the housing 220 with the wafers in an upright orientation. In one embodiment, the upright orientation may be a front side up orientation. In another embodiment, the upright orientation may be a back side up (i.e. front side down) orientation. Thus, the phrase upright orientation is used herein to differentiate from an inverted orientation which is opposite the upright orientation. If the upright orientation is a front side up orientation, then the inverted orientation is a front side down orientation. If the upright orientation is a front side down orientation, then the inverted orientation is a front side up orientation. The wafers are altered from the upright orientation to the inverted orientation during the rotation of the housing 220 by 180° as described herein.

The second robot apparatus 700 may be known as the process robot apparatus in some embodiments. The second robot apparatus 700 may be configured to insert the wafers into and remove the wafers from the cavity 225 of the housing 200 via the second opening 229 in the second side 228 of the housing 220. Thus, while the first robot apparatus 600 interacts with the cavity 225 of the housing 220 via the first opening 227 in the first side 226 of the housing 220, the second robot apparatus 700 interacts with the cavity 225 of the housing 220 via the second opening 229 in the second side 228 of the housing 220. In an embodiment, the first robot apparatus 600 may insert the wafers into and remove the wafers from the cavity 225 of the housing 220 while the wafers are in the upright orientation and the second robot apparatus 700 may insert the wafers into and remove the wafers from the cavity 225 of the housing 220 while the wafers are in the inverted orientation. This will be described in more detail below with reference to FIGS. 13A-13I.

The second robot apparatus 700 may transport the wafers between the wafer flipping device 200 and the tool 750. Specifically, the second robot apparatus 700 may remove the wafers from the cavity 225 of the housing 220 of the wafer flipping device 200 and transport the wafers to the tool 750 for processing. Furthermore, the second robot apparatus 700 may transport the wafers from the tool 750 back to the cavity 225 of the housing 220 of the wafer flipping device 200 after the wafers have been processed by the tool 750.

The tool 750 may be any of a number of process tools used for semiconductor processing. The tool 750 may be a coating tool, a developing tool, a lithography tool, an etching tool, a deposition tool, an ion implantation tool, or any other tool typically used in a semiconductor manufacturing process.

Each of the first and second robot apparatuses 600, 700 may take on any of various different configurations. The first and second robot apparatuses 600, 700 may each have at least one end effector for holding the wafers during transport between the wafer flipping device 200 and the storage pod 650 or the tool 750. The first and second robot apparatuses 600, 700 may hold the wafers with pins, vacuum, or other structure. The first and second robot apparatuses 600, 700 may be capable of moving in different directions depending on the travel required to transport wafers between the storage pod 650 and the wafer flipping device 200 in the case of the first robot apparatus 600 and between the tool 750 and the wafer flipping device 200 in the case of the second robot apparatus 700. The first and second robot apparatuses 600, 700 may be configured to move along any of one or more directions including one or more horizontal linear directions, opposing vertical linear directions, and opposing rotational directions.

The first robot apparatus 600 may insert wafers into and remove wafers from the cavity 225 by moving in a direction parallel to the rotational axis R-R of the housing 220. Similarly, the second robot apparatus 700 may insert wafers into and remove wafers from the cavity 225 by moving in a direction parallel to the rotational axis R-R of the housing 220. However, the first and second robot apparatuses 600, 700 insert and remove wafers from the housing 220 at the opposite sides/ends of the housing 220. That is, in some embodiments the first robot apparatus 600 always and only inserts wafers into and removes wafers from the cavity 225 of the housing 220 via the first opening 227 in the first side 226 of the housing 200. In some embodiments, the second robot apparatus 700 always and only inserts wafers into and removes wafers from the cavity 225 of the housing 220 via the second opening 229 in the second side 228 of the housing 200.

Referring sequentially to FIGS. 13A-13I, the operation, function, and use of the wafer handling system 1000 will be described. FIG. 13A is a front view of the wafer flipping apparatus 100 illustrating a first set of wafers 510 being inserted into the cavity 224 of the housing 220 through the front frame opening 115 of the front frame 111 and through the first opening 227 in the first side 226 of the housing 220. While the first robot apparatus 600 is not depicted in FIG. 13A, it should be appreciated that the first robot apparatus 600 would be carrying the first set of wafers 510 and inserting the first set of wafers 510 into the cavity 225 of the housing 200. The first robot apparatus 600 may carry and insert one of the wafers 510 into the cavity 225 at a time, or the first robot apparatus 600 may carry all four of the wafers 510 of the first set for insertion into the cavity 225 at the same time.

In this embodiment, there are four wafers in the first set of wafers 510. Furthermore, the housing cavity 225 of the housing 200 comprises eight of the slots 230. Thus, once inserted into the cavity 225, the first set of wafers 510 will fill half of the slots 230 of the cavity 225. In the exemplified embodiment, the first set of wafers 510 are inserted into the cavity 225 of the housing 220 in the upright orientation. In this embodiment, the upright orientation comprises front surfaces 511 of the wafers 510 facing upwardly and back surfaces 512 of the wafers 510 facing downwardly.

Turning to FIG. 13B, the first set of wafers 510 are illustrated in the cavity 225 supported by a first set of the slots 230. In the exemplified embodiment, the first set of wafers 510 are located within the top four slots 230 but the first set of wafers 510 could be located in any four of the slots 230 in alternative embodiments.

Referring to FIGS. 13B and 13C, once the first set of wafers 510 are inserted into the cavity 225 through the first opening 227 in the first side 226 of the housing 220, the actuator assembly 250 may be actuated to secure/clamp the first set of wafers 510 in place. Specifically, the actuator assembly 250 may be activated to move the actuator member 252 vertically upward (compare FIG. 13B with FIG. 13C). The movement of the actuator member 252 vertically upward also moves the first and second gripper elements 262, 282 vertically upward to clamp the wafers 510 in the slots 230. As a result of the vertical movement of the first and second gripper elements 262, 282, the rib-like protrusions 249 of the first gripper element 252 (and a similar rib-like protrusion 279 of the second gripper element 282) move vertically upward into the slots 230 and securely clamp and hold the wafers 510 in place. This prevents the wafers 510 from moving and rattling within the cavity 225 of the housing 220, particularly during rotation of the housing 220 as described herein. In some embodiments, the clamping may occur in other ways using other mechanisms. In still other embodiments, the clamping step may be omitted if it is determined to be unnecessary for a specific use-case.

Referring to FIGS. 13D and 13E, after the actuation assembly 250 is activated to clamp the wafers 510 (or, if this step is omitted, after the wafers 510 are inserted into the slots 230 of the cavity 225 of the housing 220), the housing 220 may be rotated 180°. This is shown in FIGS. 13D and 13E, whereby in FIG. 13D the actuation member 252 is located at a top of the housing 220 and in FIG. 13E the actuation member 252 is located at a bottom of the housing 220. Due to the 180° rotation of the housing 220, the wafers 510 in the cavity 225 have been inverted from the upright orientation in which they were inserted into the cavity 225 to an inverted or upside-down orientation. Thus, in FIG. 13E, the wafers 510 are oriented so that their back side 512 faces upwardly and their front side 511 faces downwardly. Of course, if the wafers 510 were inserted into the cavity 225 in the inverted or upside-down orientation, after the 180° rotation the wafers 510 would be in the upright orientation.

Referring to FIG. 13F, after the housing 220 is rotated 180°, several steps may occur simultaneously or in different sequences. The first set of wafers 510 may be removed from the cavity 225 of the housing 220 via the second opening 229 in the second side 228 of the housing 220. In the exemplified embodiment, the first set of wafers 510 are removed from the cavity 225 of the housing 220 via the second opening 229 while the first set of wafers 510 are in the inverted or upside-down orientation whereby the back side/surface 512 faces upwardly and the front side/surface 511 faces downwardly. The first set of wafers 510 may be removed from the cavity 225 by the second robot apparatus 700 as described above. The second robot apparatus 700 may remove the second set of wafers 510 one wafer at a time or multiple wafers at a time. The second robot apparatus 700 may transport the first set of wafers 510 from the housing 220 to the tool 750 (see FIG. 12) for processing. The wafers 510 may be removed from the cavity 225 and carried to the tool 750 in the inverted orientation so that processing may take place on the back side 512 of the wafers 510.

Either while the first set of wafers 510 are being removed from the cavity, before the first set of wafers 510 are removed, or after the first set of wafers 510 are removed from the cavity 225, a second set of wafers 520 may be inserted into the cavity 225 of the housing 220 via the first opening 227 in the first side 226 of the housing 220. The second set of wafers 520 may be in the upright orientation when being inserted into the cavity 225 of the housing 220 such that the front side 521 of the wafers 520 faces upwardly and the back side 522 of the wafers 521 faces downwardly. Of course, the second set of wafers 520 could alternatively be placed into the cavity 225 in the inverted orientation. The second set of wafers 520 may be inserted into the cavity 225 via the first opening 227 in the first side 226 of the housing 220 while (or before or after) the first set of wafers 510 are removed from the cavity 225 via the second opening 229 in the opposite second side 228 of the housing 220. The removal of the first set of wafers 510 and the insertion of the second set of wafers 520 occur while the housing 220 remains in its inverted position. With the removal of the first set of wafers 510 and the insertion of the second set of wafers 520, there are still only four wafers in the cavity 225, although the cavity 225 has the capacity to hold eight wafers in the exemplified embodiment.

Thus, as shown in FIG. 13G, after the second robot apparatus 700 removes the first set of wafers 510 from the cavity 225 of the housing 220, the second robot apparatus 700 may insert a third set of wafers 530 into the cavity 225 of the housing 220 via the second opening 229 in the second side 228 of the housing 220. The third set of wafers 530 may be wafers that have already been processed by the tool 750 (see FIG. 12). Thus, the third set of wafers 530 may have previously been inserted into the cavity 225 of the housing 220 by the first robot apparatus 600 in the upright orientation, rotated 180°, removed from the cavity 225 of the housing 220 by the second robot apparatus 700, transported to the tool 750, and processed by the tool 750. Once the processing of the third set of wafers 530 is complete, the third set of wafers 530 may be reintroduced/reinserted into the cavity 225 of the housing 229 via the second opening 229 in the second side 228 of the housing 220 by the second robot apparatus 700. The third set of wafers 530 may be introduced into the cavity 225 of the housing 220 while in the inverted (front side 531 down and back side 532 up) orientation. Thus, all inverting of the wafers may occur within the wafer flipping device 200, and the robot apparatuses 600, 700 may simply carry/transport the wafers from one location to another without changing the orientation of the wafers.

If there are no wafers in the tool 750 after the second set of wafers 520 are inserted into the cavity 225, then no third set of wafers needs to be inserted into the cavity 225 at this time. That is, if the first set of wafers 510 are the first wafers to be processed by the tool 750, then until the first set of wafers 510 are finished being processed there may not be any wafers to insert into the cavity 225 of the housing 220 via the second opening 229 in the second side 228. As such, it should be appreciated that minor variations to the flow of operation are possible depending on the processes occurring before and after the wafers are introduced into the cavity 225 of the housing 220.

Back to the exemplified embodiment, after the third set of wafers 530 (which have already been processed by the tool 750) are inserted into the cavity 225 of the housing 220 via the second opening 229 in the second side 228 of the housing 220, there may be eight wafers in the cavity 225 (four of the second set of wafers 520 and four of the third set of wafers 530). Thus, in an embodiment, all of the slots 230 of the cavity 225 may be filled by one of the wafers 520, 530.

FIG. 13H illustrates the wafer flipping device 200 with the eight wafers 520, 530 in the cavity 225 of the housing 220. At this point, the actuator assembly 250 may be activated to clamp the wafers 520, 530 in place as described above. Finally, the housing 220 may be rotated 180° to invert the wafers 520, 530 held therein. In FIG. 13H, the second set of wafers 520 are in the top slots 230 of the cavity 225 in the upright orientation (i.e., with their front sides 521 facing upwardly and their back sides 522 facing downwardly). Furthermore, in FIG. 13H the third set of wafers 520 are in the bottom slots 230 of the cavity 225 in the inverted or upside-down orientation (i.e., with their back sides 532 facing upwardly and their front sides 531 facing downwardly). After the housing 220 is rotated 180°, the wafers 520, 530 are inverted. Thus, in FIG. 13I the second set of wafers 520 are in the inverted/upside-down orientation with their back sides 522 facing upwardly and their front sides 521 facing downwardly while the third set of wafers 520 are in the upright orientation with their front sides 531 facing upwardly and their back sides 532 facing downwardly.

Although no figures are provided to show the next steps, they will be described here. Basically, the next steps is more of the same of what has already been described, which is why additional figures are not being used to illustrate this. After the housing 220 has been rotated from its inverted state (FIG. 13H) to its upright state (FIG. 131), the following may occur. First, the third set of wafers 530 may be removed from the cavity 225 of the housing 220 via the first opening 227 in the first side 226 of the housing 220 by the first robot apparatus 600. The third set of wafers 530 (which were previously processed by the tool 750, and may be referred to as “processed wafers”) may be transported to the pod 650 for storage or to some other location for storage or further processing. Next, the first set of wafers 510 which were moved from the housing 220 to the tool 750 in FIG. 13F for processing will be returned to the cavity 225 of the housing 220 via the second opening 229 in the second side 228 of the housing 220. This occurs once the processing of the first set of wafers 510 is complete. The first set of wafers 510 will remain in the same inverted orientation that they were in during processing as they are placed back into he cavity 225 of the housing 220. During this process, the first set of wafers 510 may be inserted into the slots 230 of the cavity 225 that were previously vacated by the third set of wafers 530.

Next, the second set of wafers 520 that were inserted into the cavity 225 of the housing 220 by the first robot apparatus 600 in FIG. 13G may be removed from the cavity 225 of the housing 220 by the second robot apparatus 700. The second set of wafers 520 are now inverted due to the rotation of the housing 220 illustrated in FIGS. 13H and 13I. The second set of wafers 520 may be removed from the cavity 225 of the housing 220 by the second robot apparatus 700 and transported to the tool 750 for processing.

Finally, a fourth set of wafers may be inserted into the cavity 225 of the housing 220 via the first opening 227 in the first side 226 of the housing 220. The fourth set of wafers may be in the upright orientation, and may be inserted into the cavity 225 of the housing 220 by the first robot apparatus 600. Thus, at this stage the third set of wafers 530 are in the pod 650 or other storage location, the fourth set of wafers are in the cavity 225 in the upright orientation, the first set of wafers 510 are in the cavity 225 in the inverted orientation, and the second set of wafers 510 are in the tool 750 for processing. This may continue with additional sets of wafers being inserted into the cavity 225 as other sets of wafers are inserted into the cavity 225, inverted, and removed for processing by the tool 750.

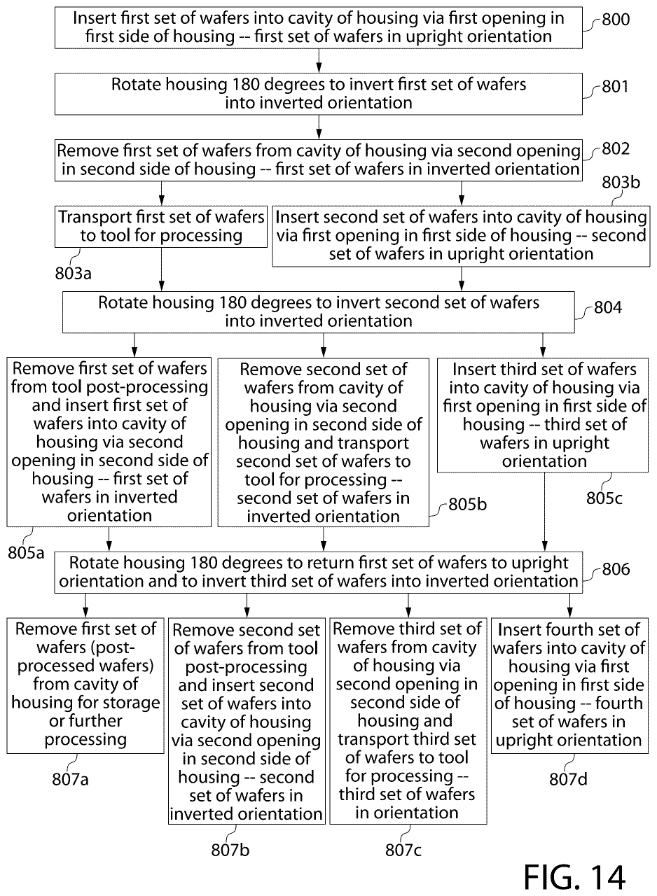

Referring to FIG. 14, the operation will be described accompanied by a flow chart. At step 800, a first set of wafers may be inserted into the cavity 225 of the housing 220 via the first opening 227 in the first side 226 of the housing 220. The first set of wafers may be transported (such as by a robot) from a pod (such as pod 650 shown in FIG. 12) to the cavity 225 of the housing 220. The first set of wafers may be in an upright orientation (front side facing upwardly, back side facing downwardly). Next, the first set of wafers may be clamped within the cavity 225 as described, although this step may be optional in some embodiments. Next, at step 801, the housing 220 may be rotated 180° to invert the first set of wafers from the upright orientation to an inverted orientation (front side facing downwardly, back side facing upwardly). Next at step 802, the first set of wafers may be removed from the cavity 225 of the housing 220 via the second opening 229 in the second side 228 of the housing 220. The first set of wafers may still be in the inverted orientation during this removal step.

Next, at step 803a, the first set of wafers may be transported to a tool (such as the tool 750 in FIG. 12) for processing. The first set of wafers may remain in the inverted orientation as they are transported to the tool and during processing by the tool. Furthermore, at step 803b, a second set of wafers may be inserted into the cavity 225 of the housing 220 via the first opening 227 in the first side 226 of the housing 220. The second set of wafers may be inserted into the housing 220 in the upright orientation. Steps 803a and 803b may be done simultaneously or in any order (either step 803a before step 803b or step 803b before step 803a).

Next, at step 804, the housing 220 may once again be rotated 180°. This will rotate the housing 220 back to its original upright orientation. The rotation of the housing 220 at step 804 will invert the second set of wafers which remain in the cavity 225 from the upright orientation into the inverted orientation. At this point, the second set of wafers are in the cavity 225 in the inverted orientation and the first set of wafers are in the tool being processed.

Next, at step 805a, the first set of wafers may be removed from the tool after the processing is complete. Thus, the first set of wafers may be post-processed wafers at this stage. The first set of wafers may then be inserted into the cavity 225 of the housing 220 via the second opening 229 in the second side 228 of the housing 220. The first set of wafers may still be in the inverted orientation as they reside within the cavity 225 of the housing 220. At step 80b, the second set of wafers may be removed from the cavity 225 of the housing 220 via the second opening 229 in the second side 228 of the housing 220. The second set of wafers may be transported to the tool 750 for processing since the first set of wafers are no longer in the tool 750. The second set of wafers may remain in the inverted orientation as they are transported from the housing 220 to the tool 750 and throughout processing. Next, at step 805c, a third set of wafers may be inserted into the cavity 225 of the housing 220 via the first opening 227 in the first side 226 of the housing 220. The third set of wafers may be inserted into the cavity 225 of the housing 220 in the upright orientation. Steps 805a-c may take place in any order or sequence and some of steps 805a-c may take place simultaneously.

At this stage, the first set of wafers are located in the cavity 225 of the housing 220 in the inverted orientation, the third set of wafers are located in the cavity 225 of the housing 220 in the upright orientation, and the second set of wafers are in the tool 750 for processing.

Next, at step 806, the housing 220 is rotated 180° to return the first set of wafers to the upright orientation and to alter the third set of wafers into the inverted orientation. In some embodiments, the actuator assembly 250 may be activated to clamp/secure the wafers in place prior to each or any rotation of the housing 220.

Next, at step 807a, the first set of wafers, which are now upright and post-processed, are removed from the cavity 225 of the housing 220. The first set of wafers may be transported to a pod (such as the pod 650) for storage, or may be transported to another location for storage or further processing. At step 807b, the second set of wafers are removed from the tool 750 (post-processing) and inserted into the cavity 225 of the housing 220 via the second opening 229 in the second side 228 of the housing 220. The second set of wafers may be in the inverted orientation at this stage. Next, at step 807c, the third set of wafers may be removed from the cavity 225 of the housing 220 via the second opening 229 in the second side 228 of the housing 220. The third set of wafers may be transported to the tool 750 for processing in the inverted orientation. Next, a fourth set of wafers may be inserted into the cavity 225 of the housing 220 via the first opening 227 in the first side 226 of the housing 220. The fourth set of wafers may be in the upright orientation. Steps 807a-d may occur in any order or sequence, and some of steps 80a-d may occur simultaneously. At this stage, the first set of wafers are located in the pod 650 or elsewhere for storage or processing having been already processed by the tool 750, the second set of wafers are in the cavity 225 of the housing 220 in the inverted orientation, having already been processed by the tool 750, the third set of wafers are located in the tool 750 and are currently being or prepared to be processed in the inverted orientation, and the fourth set of wafers are in the cavity 225 of the housing 220 in the upright orientation. These steps may continue until all desired sets of wafers have been processed by the tool 750, altered back to their upright orientation within the housing 220, and then removed from the housing 220.

All insertions and removals of wafers into and/or from the first opening 227 in the front side 227 of the housing 220 may be done with the first robot apparatus 600. All insertions and removals of wafers into and/or from the second opening 229 in the second side 228 of the housing 220 may be done with the second robot apparatus 700.

The techniques and concepts described herein relate, at least in part, to the movement of substrates during semiconductor processing or device fabrication. Thus, the exact processing or fabrication steps being performed is not to be limiting of the invention in all embodiments. Rather, in an embodiment the invention may be directed to the components, structures, assemblies, and the like that are used to move or transport the substrate from one location of the system to another.

In some embodiments, the invention described herein is directed to a flipper/buffer apparatus (i.e., the wafer flipping device 200) that can hold a plurality of wafers and simultaneously rotate all of the wafers between upright and inverted orientations. The flipper/buffer apparatus may have a cavity that can be accessed by a first robot apparatus through a first opening on a first side thereof and by a second robot apparatus through a second opening on a second side thereof. The flipper/buffer may act as a means for inverting wafers prior to them entering the process zone of a tool and after departing the process zone of the tool. In some embodiments, the wafers arriving and departing the flipper/buffer apparatus are upright. During processing, the wafers may be upside down or inverted. There may be two robot apparatuses, one that loads the flipper/buffer apparatus from the front end and one that handles wafers through the processes. The flipper/buffer apparatus may be the interface between the two robot apparatuses.

While the invention has been described with respect to specific examples including presently preferred modes of carrying out the invention, those skilled in the art will appreciate that there are numerous variations and permutations of the above described systems and techniques. It is to be understood that other embodiments may be utilized, and structural and functional modifications may be made without departing from the scope of the present invention. Thus, the spirit and scope of the invention should be construed broadly as set forth in the appended claims.

1. A wafer handling system comprising:
a wafer flipping apparatus comprising:
a support member;
a housing rotatably coupled to the support member, the housing comprising a cavity, a first side having a first opening into the cavity, and a second side having a second opening into the cavity, the cavity comprising a plurality of slots each configured to receive a wafer such that the cavity is configured to hold a plurality of the wafers in a spaced apart manner;
wherein the wafers are configured to be inserted into and removed from the cavity through both of the first and second openings; and
wherein during rotation of the housing relative to the support member, the wafers in the cavity are configured to be inverted.

2. The wafer handling system according to claim 1 further comprising:
a first robot apparatus configured to insert a first set of wafers in a front side up orientation into the cavity via the first opening, after which the housing is rotated 180° so that the first set of wafers in the cavity are in a front side down orientation; and
a second robot apparatus configured to remove the first set of wafers in the front side down orientation from the cavity via the second opening and to transport the first set of wafers for processing in the front side down orientation, after which the first set of wafers become a first set of post-processed wafers.

3. The wafer handling system according to claim 2 further comprising:
the second robot apparatus configured to insert the first set of post-processed wafers in the front side down orientation into the cavity via the second opening, after which the housing is rotated 180° so that the first set of post-processed wafers in the cavity are in the front side up orientation; and
the first robot apparatus configured to:
remove the first set of post-processed wafers in the front side up orientation from the cavity via the first opening; and
insert a second set of wafers in the front side up orientation into the cavity via the first opening.

4. The wafer handling system according to claim 1 further comprising:
a first robot apparatus configured to insert wafers into and remove wafers from the cavity of the housing via the first opening; and
a second robot apparatus configured to insert wafers into and remove wafers from the cavity of the housing via the second opening.

5. The wafer handling system according to claim 4 further comprising:
a storage pod configured to store the wafers;
a tool configured to perform a processing operation on the wafers;
wherein the first robot apparatus is configured to move the wafers between the storage pod and the housing; and
wherein the second robot apparatus is configured to move the wafers between the tool and the housing.

6. The wafer handling system according to claim 1 wherein the housing is configured to be rotated relative to the support member about a rotational axis that intersects both of the first and second openings.

7. The wafer handling system according to claim 6 wherein the wafers are configured to be maneuvered in a direction parallel to the rotational axis during insertion of the wafers into the cavity through either one of the first and second openings.

8. The wafer handling system according to claim 1 wherein the support member comprises a first surface, a second surface opposite the first surface, and a through-hole extending from the first surface to the second surface, and wherein at least a portion of the housing extends into the through-hole.

9. The wafer handling system according to claim 1 further comprising:
the housing comprising a bottom wall, a top wall, a first side wall coupled to the bottom and top walls, and a second side wall coupled to the bottom and top walls, the first side wall comprising a first plurality of slits extending from the first side of the housing to the second side of the housing and the second side wall comprising a second plurality of slits extending from the first side of the housing to the second side of the housing, the first and second plurality of slits in the first and second side walls, respectively, being spaced apart in a direction between the bottom and top walls, and wherein each of the wafers is configured to be supported in the cavity by one of the first plurality of slits in the first side wall and one of the second plurality of slits in the second side wall.

10. The wafer handling system according to claim 9 further comprising:
the first side wall comprising an inner surface that faces the cavity, an outer surface opposite the inner surface, and a first wall opening extending between the inner and outer surfaces of the first side wall that is elongated in a direction between the top and bottom walls of the housing; and
the second side wall comprising an inner surface that faces the cavity, an outer surface opposite the inner surface, and a second wall opening extending between the inner and outer surfaces of the second side wall that is elongated in the direction between the top and bottom walls of the housing.

11. The wafer handling system according to claim 10 further comprising:
a first gripper member comprising a first gripper body that is adjacent to the outer surface of the first side wall and a first gripper element that extends through the first wall opening in the first side wall;
a second gripper member comprising a second gripper body that is adjacent to the outer surface of the second side wall and a second gripper element that extends through the second wall opening in the second side wall; and
wherein the first gripper element is movable relative to the first gripper body and relative to the first side wall in the direction between the top and bottom walls of the housing and the second gripper element is movable relative to the second gripper body and relative to the second side wall in the direction between the top and bottom walls to secure the wafers during rotation of the housing.

12. The wafer handling system according to claim 11 further comprising:
the first gripper element comprising a plurality of first gripper slits;
the second gripper element comprising a plurality of second gripper slits; and
wherein the first and second gripper elements are alterable between: (1) a non-clamped position wherein each of the plurality of first gripper slits is aligned with one of the first plurality of slits of the first side wall and each of the plurality of second gripper slits is aligned with one of the second plurality of slits of the second side wall; and (2) a clamped position wherein each of the plurality of first gripper slits is at least partially unaligned with the one of the first plurality of slits of the first side wall and each of the plurality of second gripper slits is at least partially unaligned with the one of the second plurality of gripper slits of the second side wall to clamp and secure the wafers between the first gripper element and the first side wall and between the second gripper element and the second side wall.

13. The wafer handling system according to claim 11 further comprising at least one actuation assembly coupled to the first and second gripper members, and wherein actuation of the actuation assembly moves the first and second gripper elements relative to the first and second side gripper bodies, respectively.

14. The wafer handling system according to claim 1 wherein the wafer flipping apparatus comprises:
a wafer flipping device that comprises the support member and the housing; and
a frame having frame walls that at least partially enclose the wafer flipping device.

15. The wafer handling system according to claim 14 wherein the frame walls comprise:
a front frame wall having a front frame opening that is aligned with the first opening in the first side of the housing when the housing is in an upright orientation and in an inverted orientation; and
a rear frame wall having a rear frame opening that is aligned with the second opening in the second side of the housing when the housing is in the upright orientation and in the inverted orientation; and
wherein the housing is rotated 180° between the upright and inverted orientations.

16. The wafer handling system according to claim 1 further comprising:
a ring member rotatably coupled to the support member; and
the housing being affixed to the ring member so that the ring member and the housing rotate together relative to the support member.

17. A wafer handling method comprising:
a) inserting a first set of wafers into a cavity of a housing via a first opening in a first side of the housing with the first set of wafers in a first upright orientation;
b) rotating the housing 180° to invert the first set of wafers into a first inverted orientation;
c) removing the first set of wafers from the cavity of the housing via a second opening in a second side of the housing while the first set of wafers remain in the first inverted orientation.

18. The wafer handling method according to claim 17 further comprising:
d) performing a first processing operation on the first set of wafers while the first set of wafers remain in the first inverted orientation;
e) after completion of step d), inserting the first set of wafers into the cavity of the housing via the second opening in the second side of the housing while the first set of wafers remain in the first inverted orientation;
f) rotating the housing 180° to return the first set of wafers to the first upright orientation.

19. The wafer handling method according to claim 18 further comprising:
g) removing the first set of wafers from the cavity of the housing via the first opening in the first side of the housing while the first set of wafers are in the first upright orientation.

20. The wafer handling method according to claim 19 further comprising:
e-1) inserting a second set of wafers into the cavity of the housing via the first opening in the first side of the housing with the second set of wafers in a second upright orientation; and
wherein step e) and step e-1) occur simultaneously or consecutively with either of step e) or step e-1) preceding the other; and
wherein during step f), the second set of wafers become inverted.

21.-31. (canceled)
